(19) United States
(12) Patent Application Publication
(10) Pub. No.: US 2026/0087297 A1
(43) Pub. Date: Mar. 26, 2026

(54) FLEXIBLE PROTECTED ELECTRONIC TAG FOR APPLICATION ON A PRODUCT AND PRODUCT COMPRISING THE FLEXIBLE PROTECTED ELECTRONIC TAG

(71) Applicant: AUTHENA AG, Zug (CH)

(72) Inventors: Matteo Panzavolta, Rüischlikon (CH); Dejan Milenovic, Horgen (CH); Milosz Tokarski, Wroclaw (PL)

(21) Appl. No.: 19/108,777

(22) PCT Filed: Sep. 4, 2023
(86) PCT No.: PCT/EP2023/074150

§ 371 Date: Mar. 5, 2025

(30) Foreign Application Priority Data
Sep. 8, 2022 (CH) CH001054/2022

(51) Int. Cl. G06K 19/077; H05K 1/02

(52) U.S. Cl. CPC G06K 19/07749; H05K 1/0277; H05K 2201/09027; H05K 2201/2036

(57) ABSTRACT

The disclosure relates to a flexible protected electronic tag for application on a product, and to a product and/or a packaging comprising the flexible protected electronic tag, which comprises a radio frequency identification circuit with an antenna, wherein the flexible protected electronic tag further comprises a flexible circuit layer, having a product side configured to be attached to the product and a top side, wherein the flexible circuit layer comprises the radio frequency identification circuit. The flexible protected electronic tag further comprises a spacer element arranged laterally next to the radio frequency identification circuit and extending from the top side of the flexible circuit layer vertically beyond the radio frequency identification circuit, thereby forming an air gap between the top of the spacer element and the top of the radio frequency identification circuit.

### FIELD OF THE DISCLOSURE

The present disclosure relates to a flexible protected electronic tag for application on a product, to a product comprising the flexible protected electronic tag and to a packaging for a product comprising the flexible protected electronic tag. Specifically, the present disclosure relates to a flexible protected electronic tag for application on a product comprising a radio frequency identification circuit with an antenna.

### BACKGROUND OF THE DISCLOSURE

Conventional tags are attached to a product container or products themselves, for example by a tie, or by using an adhesive (i.e. a tag in the form of a label). Simple tags are used to record information about the product, for example a product name, product manufacturer, instructions related to the use of the product, certifications related to the product, etc. Tags can also feature a printed machine-readable visual code, for example in the form of a barcode or a QR code, which enables a barcode scanner, for example, to identify the product. These types of tags are typically made from die-cut plastics, papers, metals, or other materials and have information printed on them. Such tags are in everyday use, from food items to cardboard shipping boxes.

More recent developments in the field of tags include the use of electronic circuitry, in particular radio frequency identification (RFID) circuitry, to enable a product scanner to read digital information from the tag electronically. RFID tags have some advantages over machine-readable visual code, for example, they do not require a line of sight with a scanner, and they are able to store more data. Such tags are gaining widespread use, for example in the airline industry, where luggage is typically tracked using an adhesive tag containing an RFID circuit.

Tamper-evident labels are also known which have one or more indicators or barriers to entry which, if breached or missing, provide visible evidence that tampering has occurred. Items such as over-the-counter drugs and packaging materials use these types of labels on their products. Tamper-evident labels are attached to the product or container in such a way as to prevent access to the product or container without leaving visible evidence. For example, tamper-evident labels feature slits or weakened portions, or particular types of adhesive, such that attempted removal of the tamper-evident label results in visible damage.

In particular, conventional electronic tags are sensitive when it comes to load applied on the tag. Load applied on a tag could harm or destroy the electronics inside the tag, which could destroy the functionality of the tag. In particular, for high weight applications like the metal industry, the glass industry or the rock industry, the only currently known possibility to protect electronic tags applied on for example glass panels, stone piles or metal beams is to place/apply the tags on the side of the products, which is in particular not possible with thin products like metal sheets or glass panels. In this case, the tags do not get destroyed when a plurality of the products are stacked on top of each other due to the product weight. Nevertheless, the tags conventionally could still be destroyed in case they face a side impact for example during transportation.

Hard tags are also known and used for products where difficult conditions or surroundings may harm the tag. Such harsh conditions are for example possible impacts, shocks or specific chemical conditions, which might affect the functionality of the tag. To protect the hard tag, in particular to protect the electronics inside the hard tag, a closed and robust housing is conventionally used, which completely surrounds the electronics placed inside. A mechanical load applied on such a hard tag does still conveys the mechanical load to the electronics placed inside, which most of the times destroys the functionality of the electronic tag. In addition, these hard tags are not flexible, which means that they can not be applied on all necessary surfaces. Further, hard tags are easy to remove without destroying the tag.

The US 2015/060554 A1 relates to an RFID tag including an inlay having a sheet-like shape and including an antenna and an IC chip electrically connected to the antenna, an outer covering member that covers the inlay, the outer covering member having a planar shape and including a main surface and a rear surface, and a frame part arranged on at least one of the main surface and the rear surface. This document does not disclose anything, which destroys the RFID tag automatically in case it is removed or peeled off.

US 2019/095773 A1 relates to an RFID label with protection of the RFID function includes an RFID transponder chip and a carrier substrate, on which the RFID transponder chip is disposed. Furthermore, at least one structure element in vertical projection is disposed laterally offset from the RFID transponder chip. This document does not disclose anything, which destroys the RFID tag automatically in case it is removed or peeled off.

EP 1 562 140 A2 relates to a paper-like RFID tag fabricated by bonding bumps of an RFID chip to an antenna to connect the chip to the antenna, the antenna being formed by a metal foil bonded onto a base film or a base tape, providing a protecting material around the RFID chip so that an upper surface thereof becomes higher than that of the RFID chip, to constitute an RFID thread, and inlaying the RFID thread in between first and second paper layers to afford a paper-like structure. This document does not disclose anything, which destroys the RFID tag automatically in case it is removed or peeled off.

### SUMMARY OF THE DISCLOSURE

It is an object of the present disclosure to provide a flexible protected electronic tag for application on a product, a product with the flexible protected electronic tag and a packaging with the flexible protected electronic tag. In particular, it is an object of the present disclosure to provide a flexible protected electronic tag, a product with the flexible protected electronic tag and a packaging with the flexible protected electronic tag, which do not have at least some of the disadvantages of the prior art.

According to the present disclosure, these objects are addressed by the features of the independent claims. In addition, further advantageous embodiments follow from the dependent claims and the description.

According to the present disclosure, a flexible protected electronic tag for application on a product is specified. The flexible protected electronic tag typically comprises a radio frequency identification circuit (RFID) with an antenna. Flexible means that at least some parts or portions of the protected electronic tag are bendable. The flexible protected electronic tag comprises, according to the present disclosure, a flexible circuit layer, having a product side, which is configured to be attached to the product, and a top side arranged opposite to the product side, wherein the flexible circuit layer comprises the radio frequency identification circuit. The radio frequency identification circuit is for example implemented as an inlay, which comprises the electronics including the antenna of the radio frequency identification circuit. In this scenario, the flexible circuit layer comprises the inlay with the radio frequency identification circuit.

According to the present disclosure, the flexible protected electronic tag further comprises a spacer element arranged laterally next to the radio frequency identification circuit. The spacer element extends from the top side of the flexible circuit layer vertically beyond the radio frequency identification circuit, thereby forming an air gap between the top of the spacer element and the top of the radio frequency identification circuit. The spacer element is for example arranged on a portion of the flexible circuit layer, which is arranged next to the radio identification circuit. The spacer element has for example a specific height, such that the top of the spacer element reaches higher compared to the top of the radio frequency identification circuit.

In an embodiment, the radio frequency identification circuit is completely enclosed in the flexible circuit layer. In this case, the spacer element extends beyond the top of the flexible circuit layer such that the air gap is formed between the top of the spacer element and the top of flexible circuit layer in the area of the radio frequency identification circuit. According to the present disclosure, the spacer element provides a stop on the flexible protected electronic tag, which protects the radio frequency identification circuit in case a mechanical load is applied on the flexible protected electronic tag. In other words, the mechanical load does not engage on the relatively sensitive radio frequency identification circuit, but on the spacer element. The sensitive radio frequency identification circuit is therefore advantageously protected, by the spacer element, from mechanical damage.

In an embodiment, the radio frequency identification circuit is arranged on the flexible circuit layer, or wherein the radio frequency identification circuit is at least partially arranged within the flexible circuit layer. The flexible circuit layer may comprise different layers, one of which might comprise the radio frequency identification circuit, for example as an inlay. An RFID inlay is for example just the RFID Chip (IC), antenna and substrate, typically on a film face. Arranging the radio frequency identification circuit at least partially within the flexible circuit layer advantageously protects the radio frequency identification circuit. In another embodiment, the radio frequency identification circuit is arranged on the flexible circuit layer, for example, the RFID inlay or an RFID chip is applied/glued on the flexible circuit layer, preferably on its top side, which improves the accessibility.

In an embodiment, the flexible protected electronic tag comprises a plurality of spacer elements extending from the top side of the flexible circuit layer. In this embodiment, the flexible protected electronic tag comprises for example two or more of the spacer elements. Having more spacer elements advantageously distributes the load on more spacer elements, which increases the overall possible load applicable on the flexible protected electronic tag.

In an embodiment, the plurality of the spacer elements are distributed evenly around the radio frequency identification circuit. The even distribution, for example a rotationally symmetric distribution helps to distribute the load advantageously on the plurality of the spacer elements.

In an embodiment, the flexible protected electronic tag comprises a flexible spacer element layer, which is arranged on the flexible circuit layer, preferably glued onto the flexible circuit layer, thereby forming the spacer element. The flexible spacer element layer is, for example, made of the same material as at least one portion of the flexible circuit layer. The flexible spacer element layer has for example the same flexible properties as the flexible circuit layer. In an embodiment, the flexible spacer element layer comprises a cut-out for the radio frequency identification circuit such that the radio frequency identification circuit is not covered by the flexible spacer element layer. In other words, the spacer element layer is an additional layer on the flexible circuit layer arranged at least partially next to the radio frequency identification circuit and extending beyond the top of the radio frequency identification circuit such that the air gap is formed. The flexible spacer element layer provides in particular an advantageous solution of how to form/create the spacer elements. In addition, the spacer element layer may have a relative large top surface area which advantageously helps to distribute the load applied to the flexible protected electronic tag such that the radio frequency identification circuit is hot harmed or destroyed.

In an embodiment, the flexible circuit layer has a ring cylindrical shape and wherein the flexible spacer element layer has a ring symmetrical shape and is arranged coaxially with respect to the flexible circuit layer. According to this embodiment, the flexible spacer element layer comprises a cutout, which has a circular shape, which preferably corresponds to the shape of the radio identification circuit. The ring cylindrical shape of the flexible circuit layer corresponds for example to a coin shape. Arranging both layers, the flexible circuit layer and the flexible spacer element layer coaxially with respect to each other, provides manufacturing advantages and reduces the overall installation space of the flexible protected electronic tag without the need to compromise in the applicable load on the spacer element.

In an embodiment, the spacer element extends at least partially inwards towards the top of the radio frequency identification circuit, thereby forming a cavity, which comprises the air gap. According to this embodiment, the spacer element or the plurality of the spacer element comprise for example an inclination towards the centre of the flexible protected electronic tag such that the spacer element(s) comprise a projection towards the geometrical centre, for example the centre axis, of the flexible protected electronic tag. In a further embodiment, the protrusion may extend to the geometrical centre, for example such that the radio frequency identification circuit is covered by the resulting protrusion. The air gap is arranged below this protrusion. According to this embodiment, the radio frequency identification circuit is advantageously protected by the spacer element. The spacer element forms in this embodiment for example at least partially an undercut, which forms the cavity. In other words, the spacer element extends e.g. with the inclination or comprises the protrusion (or protruding element), thereby forming the cavity. The cavity is a space enclosed at least partially by the flexible circuit layer and the spacer element (forming the undercut). Further, the spacer element forms e.g. an opening of the cavity and the cavity extends in the space beyond the opening towards the flexible circuit layer.

In an embodiment, the flexible circuit layer comprises a plurality of precuts arranged around the radio frequency identification circuit, which extend through the flexible circuit layer. For example, the plurality of precuts is distributed evenly around the radio frequency identification circuit. The precuts make it almost impossible to remove the flexible protected electronic tag from the product without destroying the radio frequency identification circuit, in particular the antenna. In a further embodiment, the radio frequency identification circuit comprises a tamper loop, which preferably extends beyond the precuts, such that a removal of the flexible protected electronic tag from the product would destroy the tamper loop of the radio frequency identification circuit. The precuts determine a predetermined breaking line in case the flexible protected electronic tag is removed/peeled off the product.

In an embodiment, the spacer element is made of a deformable material. Further, the vertical extension of the spacer element is selected in dependence of a predefined load expected to engage on the spacer element, such that the air gap between the top of the spacer element and the top of the radio frequency identification circuit is not fully compressed when the load engages on the spacer element. In other words, the vertical extension of the spacer element remains larger compared to the maximum vertical extension of the radio frequency identification circuit, when the load engages on the spacer element. When the mechanical load is applied on the spacer element of the flexible protected electronic tag, the spacer element may be compressed due to the mechanical load. According to this embodiment, the compression of the spacer element does not result in contacting of the radio frequency identification circuit. According to this embodiment, the radio identification circuit is still protected even if the predefined mechanical load engages on the spacer element. The deformable material is for example a plastic, rubber material, or a metal material.

In an embodiment, the flexible protected electronic tag comprises a product adhesion layer arranged on the product side of the flexible circuit layer and configured to attach the flexible protected electronic tag on the product. The product adhesion layer is for example a thin film of adhesive/glue configured to attach the flexible protected electronic tag rigidly on the product. The product adhesion layer is in an embodiment applied entirely or partially (for example by leaving out the precut area) on the product side of the flexible circuit layer. The product adhesion layer is an advantageously simple solution to attach the flexible protected electronic tag on the product.

In an embodiment, the flexible protected electronic tag comprises a spacer adhesion layer arranged between the spacer element and the flexible circuit layer and configured to attach the spacer element to the flexible circuit layer. The spacer adhesion layer is for example also a thin film of adhesive/glue configure to attach the spacer element(s) or the spacer element layer respectively on the flexible circuit layer. The spacer adhesion layer is an advantageously simple solution to attach the spacer element rigidly to the flexible circuit layer.

In an embodiment, the flexible protected electronic tag comprising a pressure relieve valve, which is configured to enable air exchange in and out of the air gap. The pressure relieve valve is configured to equalize the pressure inside the air gap with the pressure outside the air gap, for protecting the radio frequency identification circuit. The pressure relieve valve may be an opening in any part, which surrounds the air gap. The pressure relieve valve may further be an opening defined by a plurality of spacer elements. Further, the pressure relieve valve may be formed by a thin layer of material surrounding at least partially the air gap, which enables that air penetrates the thin layer of material thereby forming the pressure relieve valve. In a further embodiment, the pressure relieve valve is a mechanical valve comprised by the flexible protected electronic tag. In a further embodiment, the pressure relieve valve may enable air exchange only if a predefined pressure difference between the air gap and the outside is reached or surpassed. The pressure relieve valve may further be formed at least partially by the precuts. In an embodiment wherein the air gap is at least partially sealed by another product arranged on top of the flexible protected electronic tag, it may be advantages that the pressure relieve valve is arranged on the lateral side of the tag, preferably in the spacer element, which enables that the pressure relieve is enabled even if another products is arranged on the flexible protected electronic tag.

In an embodiment, the flexible protected electronic tag comprises a cover layer arranged on the top of the spacer element, preferably via a cover adhesion layer, and configured to cover at least partially the spacer element and the air gap. According to this embodiment, the cover layer is arranged on top of the flexible protected electronic tag and encloses at least partially the air gap arranged between the top of the flexible circuit layer, the cover layer and the spacer element. The cover layer advantageously protects the radio identification circuit from contamination.

In an embodiment, the cover layer comprises a hole or a plurality of holes, which is configured to enable air exchange in and out of the air gap. The hole enables that pressure differences inside the air gap and outside of the air gap are balanced. For example, in case the flexible protected electronic tag comprising the cover layer is used for airfreight applications, the different altitudes during flight and on the ground would result in different air pressures inside the air gap and outside of the air gap if no hole for air exchange were provided in the cover layer. The different air pressures could harm or destroy the flexible protected electronic tag, in particular the cover layer could be damaged. The at least one hole of the cover layer may be at least partially the pressure relieve valve.

In a further embodiment, the hole for air exchange is provided in any other part of the flexible protected electronic tag, which encloses the air gap.

In an embodiment, the product adhesion layer, the spacer adhesion layer and/or the cover adhesion layer comprise an acrylic adhesive.

In a further embodiment, the radio frequency identification circuit may comprise a near field communication (NFC) circuit, a low frequency (LF) communication circuit, a ultra high frequency (UHF) communication circuit, a combination thereof and/or any other kind of RFID communication circuit.

In a further aspect of the present disclosure, a packaging for a product comprising a flexible protected electronic tag as described above and hereinafter is specified. The packaging is for example a cardboard or wrapping material, which surrounds at least partially a product like a stone pile, a metal sheet or any other kind of high weight product.

In a further aspect of the present disclosure, a product comprising a flexible protected electronic tag as described above and hereinafter is specified. The flexible protected electronic tag is for example directly applied on the product like a stone pile, a metal sheet or any other kind of high weight product.

In the following portion of the description, further aspects of the present disclosure are specified. The individual aspects are enumerated in order to facilitate the reference to features of other aspects.
1. Flexible protected electronic tag for application on a product, the flexible protected electronic tag comprising a radio frequency identification circuit with an antenna, wherein the flexible protected electronic tag further comprises:
a flexible circuit layer, having a product side configured to be attached to the product and a top side arranged opposite to the product side, wherein the flexible circuit layer comprises the radio frequency identification circuit;
a spacer element arranged laterally next to the radio frequency identification circuit and extending from the top side of the flexible circuit layer vertically beyond the radio frequency identification circuit, thereby forming an air gap between the top of the spacer element and the top of the radio frequency identification circuit.

The enumerated aspect may further comprise any features presented above and/or hereinafter with respect to any other aspect of the present disclosure.

It is to be understood that both the foregoing general description and the following detailed description of present embodiments are intended to provide an overview or framework for understanding the nature and character of the disclosure. The accompanying drawings are included to provide a further understanding, and are incorporated into and constitute a part of this specification. The drawings illustrate various embodiments, and together with the description serve to explain the principles and operation of the concepts disclosed.

### BRIEF DESCRIPTION OF THE DRAWINGS

The present disclosure will be explained in more detail, by way of example, with reference to the drawings in which:

FIG. 1: shows a top view of a flexible protected electronic tag according to a first embodiment;

FIG. 2: shows a section view AA of the flexible protected electronic tag according to the first embodiment;

FIG. 3: shows the detail B of the side view of FIG. 2;

FIG. 4: shows an exploded view of the flexible protected electronic tag according to a second embodiment, wherein a cover layer is indicated;

FIG. 5: shows a perspective view of the flexible protected electronic tag according to the second embodiment with the cover layer;

FIG. 6: shows a perspective view of the flexible protected electronic tag according to the second embodiment without the cover layer;

FIG. 7: shows an exploded view of the flexible protected electronic tag according to a third embodiment without a cover layer;

FIG. 8: shows a perspective view of the flexible protected electronic tag according to the third embodiment;

FIG. 9: shows an exploded view of the flexible protected electronic tag according to the third embodiment with the cover layer;

FIG. 10: shows a perspective view of the flexible protected electronic tag according to the third embodiment with the cover layer;

FIG. 11: shows a conventional electronic tag without and with load applied on top of the electronic tag;

FIG. 12: shows the flexible protected electronic tag according to the second embodiment without and with load applied on top of the electronic tag;

FIG. 13: shows the flexible protected electronic tag according to a fourth embodiment without and with load applied on top of the electronic tag.

### DETAILED DESCRIPTION OF THE EMBODIMENTS

The FIGS. 1, 2, and 3 show schematically a flexible protected electronic tag 1 according to a first embodiment. The flexible protected electronic tag 1 comprises a flexible circuit layer 2, which comprises a radio frequency identification circuit 3 with an antenna 4. The flexible protected electronic tag 1 has a product side 2a, which is configured to be attached to a product 7 (for example shown in FIG. 12). The flexible protected electronic tag 1 has a top side 2b arranged opposite with respect to the product side 2a, thereby facing away from the product 7 in case the flexible protected electronic tag 1 is applied on a product 7.

The flexible protected electronic tag 1 further comprises a spacer element layer 6, which is arranged laterally next to the radio frequency identification circuit 3 and which extends from the top side 2b of the flexible circuit layer 2 vertically beyond the radio frequency identification circuit 3. The spacer element layer 6, which surrounds according to this embodiment the radio frequency identification circuit 3, forms thereby the spacer element 5. An air gap 12 is formed between the surrounding spacer element 5 and the flexible circuit layer 2, in particular the radio frequency identification circuit 3. The extension of the spacer element layer 6 provides the desired protection of the radio frequency identification circuit 3 in case a mechanical load is applied on the flexible protected electronic tag 1. The FIGS. 1 and 3 advantageously show a cavity 9, which comprises a cavity bottom 10. The cavity 9 or depression is formed by a cutout of the spacer element layer 6. The cavity bottom 10 is according to this embodiment the top side 2b of the flexible circuit layer 2.

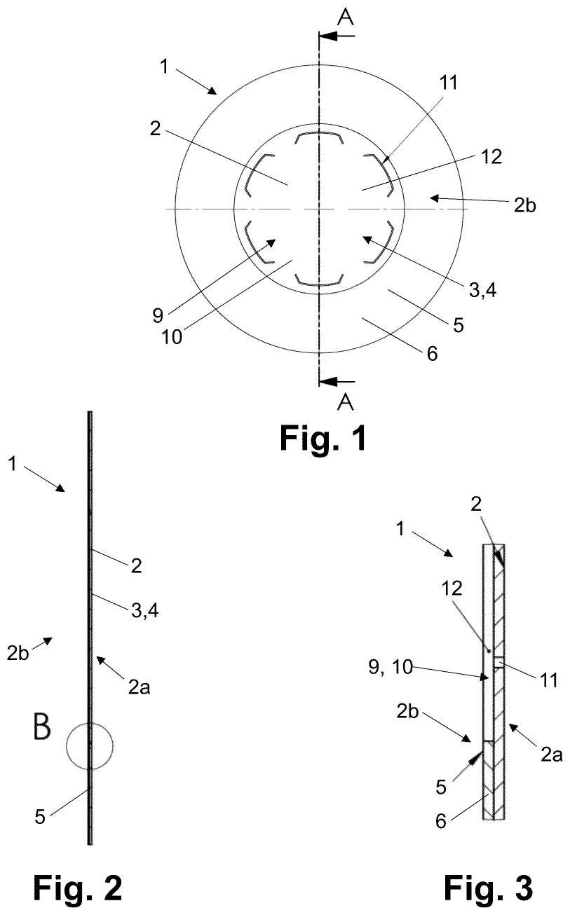

FIG. 2, which shows the cross section AA of FIG. 1, advantageously provides an impression of the thickness of the flexible protected electronic tag 1 comprising the flexible circuit layer 2 and the spacer element layer 6.

According to the first embodiment, the flexible circuit layer 2 has a circular cylindrical shape, best visible in FIG. 1. The spacer element layer 6 has a ring circular cylindrical shape and is arranged coaxially with the flexible circuit layer 2.

The flexible protected electronic tag 1 according to the first embodiment further comprises a plurality of precuts 11, best visible in FIG. 1 and FIG. 3, which are arranged/distributed evenly around the geometrical center of the flexible protected electronic tag 1. The plurality of precuts 11 have an U-shape, comprising a base line and two limbs extending from each end of the base line, wherein the limbs are directed towards the geometrical center of the flexible protected electronic tag 1. The precuts surround the radio frequency identification circuit 3 and the antenna 4 such that an attempted removal of the flexible protected electronic tag 1 from a product 7 would cause shear forces on the portions of the flexible circuit layer 2 next to the precuts 11. The precuts 11 define a predetermined breaking line, along which the flexible protected electronic tag 1 breaks. In a further embodiment, the radio frequency identification circuit 3 may comprise a tamper loop (not shown in the Figures), which extends beyond the precuts such that an attempted removal of the flexible protected electronic tag 1 would destroy the tamper loop.

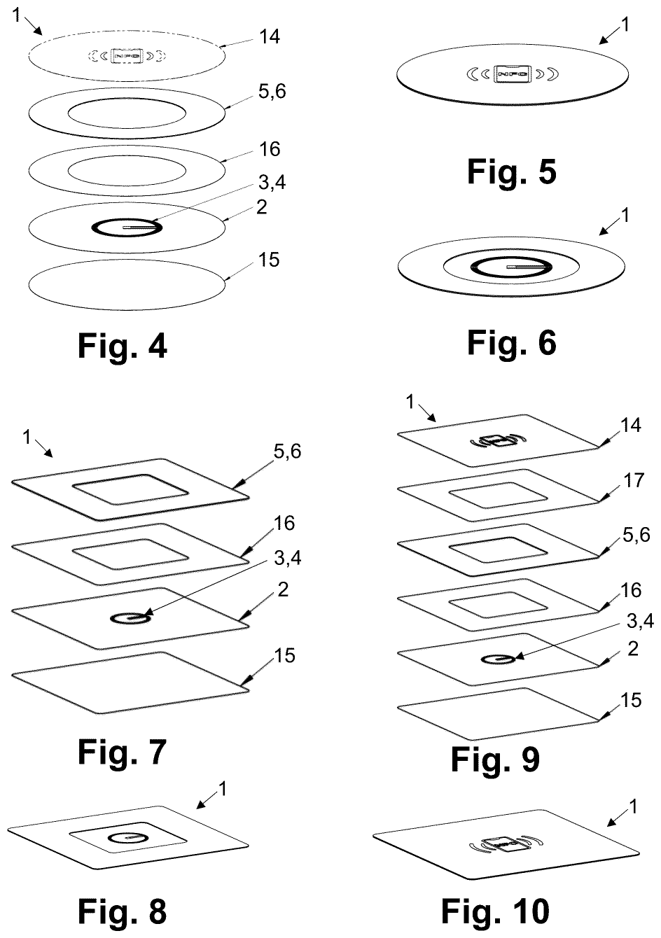

The exploded view of FIG. 4 shows advantageously the different parts/layers of the flexible protected electronic tag 1 according to a second embodiment without the precuts 11 as shown in the FIGS. 1 to 3. The flexible protected electronic tag 1 comprises the flexible circuit layer 2 with the radio frequency identification circuit 3 and the antenna 4 and the spacer element layer 6, which forms the spacer element 5. FIG. 4 further shows a product adhesion layer 15, which is, for example, a very thin film of adhesive configured to attach the flexible circuit layer 2 on the product 7, when applied. The product adhesion layer 15 is applied on the product side 2a of the radio frequency identification circuit 3. FIG. 4 further shows a spacer adhesion layer 16, which is, for example, a very thin film of adhesive configured to attach the spacer element 5 and/or the spacer element layer 6 to the flexible circuit layer 2. The spacer adhesion layer 16 is arranged on the top side 2b of the flexible circuit layer 2, best visible in FIG. 4. FIG. 4 further shows an optional cover layer 14, which has the same radius as the flexible circuit layer 2 and which is arranged on top of the spacer element layer 6 extending from the outer edge of the spacer element layer 6 to the geometrical center, thereby closing the cavity 9 and the air gap 12 from the top. The cover layer 14 advantageously protects the radio frequency identification circuit 3 from possible contaminations from the top side. The cover layer 14 is shown in FIG. 4 in dotted lines to indicate that the cover layer 14 is an optional feature. FIG. 5 shows the flexible protected electronic tag 1 in a perspective view with the cover layer 14 and FIG. 6 shows the flexible protected electronic tag 1 in a perspective view without the cover layer 14.

The FIGS. 7, 8, 9 and 10 show a third embodiment, which corresponds basically to the second embodiment. The third embodiment differs in the shape, the outer contour of the flexible protected electronic tag 1 and its components, respectively. In particular, the flexible protected electronic tag 1 has the shape of a cuboid, in particular the shape of a rectangular cuboid. As best visible in the FIGS. 7 and 9, the flexible circuit layer 2 has a rectangular shape comprising the radio frequency identification circuit 3 and the antenna 4. The spacer element layer 6 has a rectangular flat shape with a rectangular cutout for the radio frequency identification circuit 3. The product adhesion layer 15 corresponds to the shape of the flexible circuit layer 2 and the spacer adhesion layer 16 corresponds to the shape of the spacer element layer 6. FIG. 9 differs from FIG. 7 in that the flexible protected electronic tag 1 comprises the cover layer 14, which has a rectangular shape corresponding to the outer edge of the spacer element layer 6. The cover layer 14 is attached to the spacer element layer 6 via a cover adhesion layer 17. The cover adhesion layer 17 is, for example, a thin film of adhesive. FIG. 8 shows a perspective view of the flexible protected electronic tag 1 according to the third embodiment without a cover layer and FIG. 10 shows the flexible protected electronic tag 1 according to the third embodiment with a cover layer 14. The cover layer 14 according to this embodiment comprises a NFC symbol.

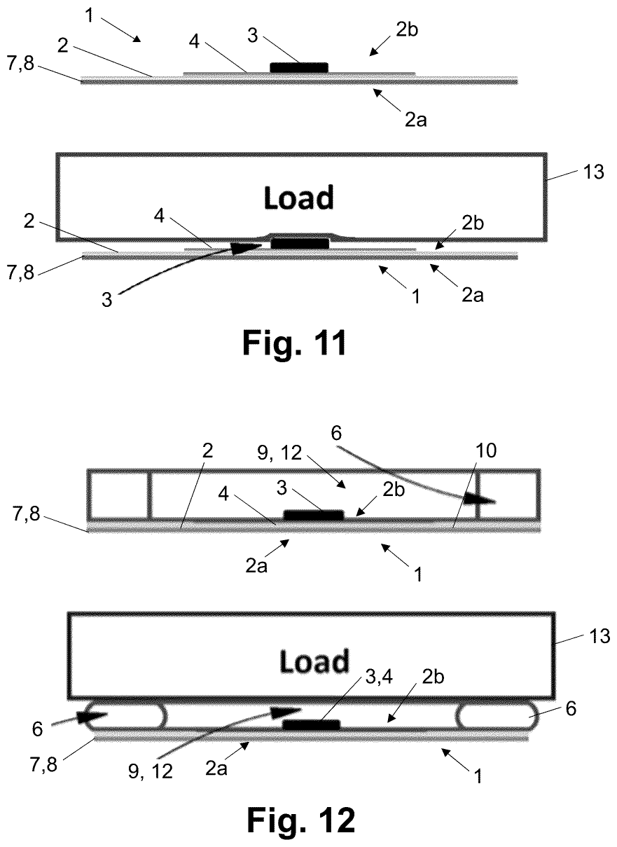

FIG. 11 shows a conventional tag 1 comprising a conventional radio frequency identification circuit 3 with an antenna 4. The conventional tag 1 has a product side 2a and a top side 2b. FIG. 11 further indicates a product 7 or a packaging 8 of the product 7 onto which the tag 1 is applied. The lower portion of FIG. 11 further shows a load 13 which engages on the tag 1, in particular on the radio frequency identification circuit 3 of the tag 1. FIG. 11 shows that the radio frequency identification circuit 3 is unprotected and will be immediately destroyed in case the applied load 13 surpasses a relatively low threshold. FIG. 11 shows the vulnerability of the conventional tag 1 regarding load applied directly to the tag 1.

FIG. 12 shows the flexible protected electronic tag 1 according to the second embodiment without the cover layer 14. The spacer element layer 6 as shown in FIG. 12 has a larger vertical extension compared to the spacer element layer 6 as shown for example in FIG. 4. The lower portion of FIG. 12 further shows a load 13 applied on the flexible protected electronic tag 1. It can be seen that the load engages only on the spacer element layer 6, which directly transfers the load/force from the load 13 to the product 7 via the flexible circuit layer 2. FIG. 12 shows that the radio frequency identification circuit 3 is protected even if the mechanical load engages on the flexible protected electronic tag 1. FIG. 12 in particular shows that the spacer element layer 6 is made of a deformable material, which is compressed when the load 13 is applied on the flexible protected electronic tag 1. The material strength, the material thickness of the spacer element layer 6, in other words, the properties of the spacer element layer 6, is or are selected such that a predefined load 13 does not compress the spacer element layer 6 to such an extent that the radio frequency identification circuit 3 is directly or indirectly contacted by the mechanical load 13. The selected deformable material is for example a plastic material or a rubber material.

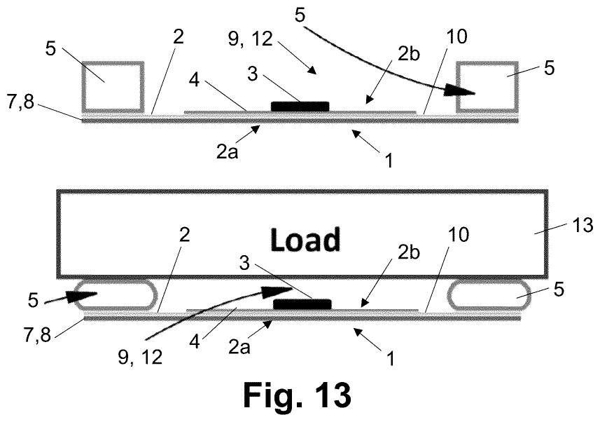

FIG. 13 shows the flexible protected electronic tag 1 according to a fourth embodiment without (upper portion) and with (lower portion) load applied on top of the electronic tag 1. FIG. 13 differs to FIG. 12 in that the spacer elements 5 are not formed by a spacer element layer 6 as shown in the FIGS. 1 to 10 and 12. The spacer elements 5 are for example single rectangular blocks of material applied on the flexible circuit layer 2. According to the embodiment as shown in FIG. 13, at least two spacer elements 5 are attached, for example via a locally applied drop of adhesive, on the top side 2b of the flexible circuit layer 2. It is also conceivable that three or more spacer elements 5 in the shape of rectangular blocks are applied, preferably evenly distributed around the radio frequency identification circuit 3, on the flexible circuit layer 2.

### LIST OF REFERENCE SYMBOLS

1 flexible protected electronic tag, RFID tag
2 flexible circuit layer
2a product side
2b top side
3 radio frequency identification circuit
4 antenna
5 spacer element
6 spacer element layer
7 product, consumer product
8 packaging
9 cavity
10 cavity bottom
11 precut
12 air gap
13 load
14 cover layer
15 product adhesion layer
16 spacer adhesion layer
17 cover adhesion layer

1. Flexible protected electronic tag for application on a product, the flexible protected electronic tag comprising:
a radio frequency identification circuit with an antenna;
a flexible circuit layer, having a product side configured to be attached to the product and a top side arranged opposite to the product side, wherein the flexible circuit layer comprises the radio frequency identification circuit; and
a spacer element arranged laterally next to the radio frequency identification circuit and extending from the top side of the flexible circuit layer vertically beyond the radio frequency identification circuit, thereby forming an air gap between the top of the spacer element and the top of the radio frequency identification circuit, wherein the flexible circuit layer comprises a plurality of precuts arranged around the radio frequency identification circuit, which extend through the flexible circuit layer

2. The flexible protected electronic tag according to claim 1, wherein the radio frequency identification circuit is arranged on the flexible circuit layer, or wherein the radio frequency identification circuit is at least partially arranged within the flexible circuit layer.

3. The flexible protected electronic tag according to claim 1, wherein the flexible protected electronic tag comprises a plurality of spacer elements extending from the top side of the flexible circuit layer.

4. The flexible protected electronic tag according to claim 3, wherein the plurality of spacer elements are distributed evenly around the radio frequency identification circuit.

5. The flexible protected electronic tag according to claim 1, wherein the flexible protected electronic tag comprises a flexible spacer element layer, which is glued onto the flexible circuit layer, thereby forming the spacer element.

6. The flexible protected electronic tag according to claim 5, wherein the flexible circuit layer has a ring cylindrical shape and wherein the flexible spacer element layer has a ring symmetrical shape and is arranged coaxially with respect to the flexible circuit layer.

7. The flexible protected electronic tag according to claim 1, wherein the spacer element extends at least partially inwards towards the top of the radio frequency identification circuit, thereby forming a cavity, which comprises the air gap.

8. The flexible protected electronic tag according to claim 1, wherein the spacer element is made of a deformable material, and wherein the vertical extension of the spacer element is selected in dependence of a predefined load expected to engage on the spacer element, such that the air gap between the top of the spacer element and the top of the radio frequency identification circuit is not fully compressed when the load engages on the spacer element.

9. The flexible protected electronic tag according to claim 1, further comprising a product adhesion layer arranged on the product side of the flexible circuit layer and configured to attach the flexible protected electronic tag to the product.

10. The flexible protected electronic tag according to claim 1, further comprising a spacer adhesion layer arranged between the spacer element and the flexible circuit layer and configured to attach the spacer element to the flexible circuit layer.

11. The flexible protected electronic tag according to claim 1, further comprising a pressure relieve valve, which is configured to enable air exchange in and out of the air gap.

12. The flexible protected electronic tag according to claim 1, further comprising a cover layer arranged on the top of the spacer element, via a cover adhesion layer, and configured to cover at least partially the spacer element and the air gap.

13. The flexible protected electronic tag according to claim 12, wherein the cover layer comprises at least one hole, which is configured to enable air exchange in and out of the air gap.

14. A packaging for a consumer product comprising the flexible protected electronic tag according to claim 1.

15. A consumer product comprising the flexible protected electronic tag according to claim 1.
